(19) United States
(12) Patent Application Publication
(10) Pub. No.: US 2024/0426955 A1
(43) Pub. Date: Dec. 26, 2024

(54) MAGNETIC RESONANCE NUMERICAL SIMULATION APPARATUS AND METHOD

(71) Applicant: Canon Medical Systems Corporation, Otawara-shi (JP)

(72) Inventor: Hidenori TAKESHIMA, Tokyo (JP)

(73) Assignee: Canon Medical Systems Corporation, Otawara-shi (JP)

(21) Appl. No.: 18/751,417

(22) Filed: Jun. 24, 2024

(30) Foreign Application Priority Data
Jun. 26, 2023 (JP) 2023-103933

(51) Int. Cl. G01R 33/56; G01R 33/563

(52) U.S. Cl. CPC G01R 33/5608; G01R 33/5607; G01R 33/56316

(57) ABSTRACT

A processing circuitry inputs, in regard to an isochromat, a value before update of magnetization, and a value before update of a partial differential for the magnetization in each of a spatial direction and/or an angular frequency direction. The processing circuitry executes an arithmetic operation of an update formula representing a time-dependent behavior of magnetic resonance, by using a part of the values before update of the magnetization, and the values before update of the partial differential, and compute, in regard to the isochromat, a value after update of the magnetization, and a value after update of the partial differential for the magnetization in a computation target direction of the spatial direction and/or the angular frequency direction.

### CROSS-REFERENCE TO RELATED APPLICATION

This application is based upon and claims the benefit of priority from prior Japanese Patent Application No. 2023-103933, filed Jun. 26, 2023, the entire contents of which are incorporated herein by reference.

### FIELD

Embodiments described herein relate generally to a magnetic resonance numerical simulation apparatus and method.

### BACKGROUND

In a magnetic resonance numerical simulation, magnetic resonance numerical imaging is simulated by using Bloch equations. The Bloch equations are equations describing a time-dependent behavior of magnetization in a magnetic field, and are basic equations of magnetic resonance imaging. As a numerical solution to Bloch equations, there is a method known as MAGSI (Magnetic Gradient Simulation of Intra-voxel dephasing). In MAGSI, a virtual molecule is set at a center of a voxel, and, on the assumption that a magnetic field in the voxel is linear, magnetization at a freely selected position in the voxel is computed by using a spatial partial differential of magnetization. However, in MAGSI, since the spatial partial differential of magnetization is computed too straightforwardly, there is room for improvement in computation efficiency.

### BRIEF DESCRIPTION OF THE DRAWINGS

FIG. 1 is a diagram illustrating a configuration example of a magnetic resonance numerical simulation apparatus according to a first embodiment.

FIG. 2 is a diagram schematically illustrating components constituting a magnetization vector M(t) that is a computation target of a magnetic resonance numerical simulation.

FIG. 3 is a diagram schematically illustrating a computation process of a magnetization vector M(t+Δt) according to a comparative example.

FIG. 4 is a diagram illustrating computation targets and contributory terms relating to the magnetization vector M(t).

FIG. 5 is a diagram schematically illustrating an arithmetic operation process of an update formula of a magnetization vector.

FIG. 6 is a diagram exemplarily illustrating a processing procedure of a magnetic resonance numerical simulation according to Example 1 of the first embodiment.

FIG. 7 is a diagram illustrating an example of a pulse sequence by a spin echo method.

FIG. 8 is a diagram exemplarily illustrating a processing procedure of a magnetic resonance numerical simulation according to Example 2 of the first embodiment.

FIG. 9 is a diagram illustrating a configuration example of a magnetic resonance numerical simulation apparatus according to a second embodiment.

FIG. 10 is a diagram exemplarily illustrating a processing procedure of a magnetic resonance numerical simulation according to Example 1 of the second embodiment.

FIG. 11 is a diagram exemplarily illustrating a processing procedure of a magnetic resonance numerical simulation according to Example 2 of the second embodiment.

### DETAILED DESCRIPTION

In general, according to one embodiment, a magnetic resonance numerical simulation apparatus includes an input unit and a numerical computation unit. The input unit is configured to input, in regard to an isochromat, a numerical value before update of magnetization, and a numerical value before update of a partial differential for the magnetization in each of a spatial direction and/or an angular frequency direction. The numerical computation unit is configured to execute an arithmetic operation of an update formula representing a time-dependent behavior of magnetic resonance by using a part of the numerical values before update of the magnetization and the numerical values before update of the partial differential, and to compute, in regard to the isochromat, a numerical value after update of the magnetization, and a numerical value after update of the partial differential for the magnetization in a computation target direction of the spatial direction and/or the angular frequency direction.

Hereinafter, a magnetic resonance numerical simulation apparatus, method and program according to the present embodiment are described in detail with reference to the accompanying drawings.

The magnetic resonance numerical simulation apparatus according to the present embodiment is a computer that executes a magnetic resonance numerical simulation. The magnetic resonance numerical simulation according to the present embodiment simulates a time-dependent behavior of magnetic resonance by a given pulse sequence, in regard to an isochromat in each of voxels set in an examination target model. Specifically, MAGSI is used in which, on the assumption that a magnetic field in the voxel is linear, magnetization at a freely selected position in the voxel is computed by using a spatial partial differential of magnetization. The magnetic resonance numerical simulation apparatus, method and program according to the present embodiment aim at enhancing the computation efficiency of magnetization and/or a partial differential.

### First Embodiment

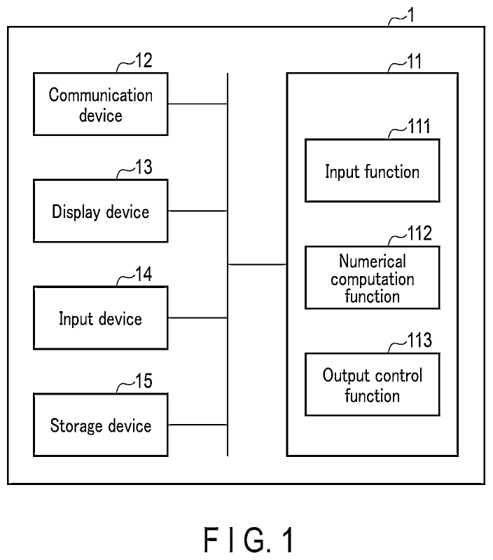

FIG. 1 is a diagram illustrating a configuration example of a magnetic resonance numerical simulation apparatus 1 according to a first embodiment. As illustrated in FIG. 1, the magnetic resonance numerical simulation apparatus 1 is a computer including processing circuitry 11, a communication device 12, a display device 13, an input device 14 and a storage device 15. Data communication between the processing circuitry 11, communication device 12, display device 13, input device 14 and storage device 15 is executed via a bus.

The processing circuitry 11 includes a processor such as a CPU (Central Processing Unit). An input function 111, a numerical computation function 112 and an output control function 113 are implemented by the processor starting a magnetic resonance numerical simulation program installed in the storage device 15 or the like. The functions 111 to 113 are not necessarily implemented by single processing circuitry. A plurality of independent processors may be combined to constitute processing circuitry, and the respective processors may implement the functions 111 to 113 by executing the magnetic resonance numerical simulation program. In addition, the functions 111 to 113 may be implemented as modules constituting the magnetic resonance numerical simulation program, or may be implemented as individual hardware.

By the input function 111, the processing circuitry 11 inputs various information used in a magnetic resonance numerical simulation. In one example, the processing circuitry 11 inputs sequence segments of a pulse sequence of a computation target. Magnetic resonance numerical computation is executed by the numerical computation function 112 with respect to each of the sequence segments. By the input function 111, the processing circuitry 11 inputs, in regard to an isochromat, a numerical value before update of magnetization and a numerical value before update of a partial differential for the magnetization in each of a spatial direction and an angular frequency direction. The isochromat means a set of nuclear magnetism moments having an identical frequency, which are set in voxels. As the numerical value before update, a numerical value manually input by the input device 14, a numerical value after update computed by the numerical computation function 112, or a preset freely chosen value may be input.

By the numerical computation function 112, the processing circuitry 11 executes an update arithmetic operation of a magnetization vector with respect to each of the sequence segments input by the input function 111. In one example, using a part of numerical values before update of magnetization and numerical values before update of partial differentials, which are input by the input function 111, the processing circuitry 11 computes an update formula expressing a time-dependent behavior of magnetic resonance (hereinafter, simply referred to as “update formula”), and computes, in regard to the isochromat, a numerical value after update of magnetization and a numerical value after update of a spatial partial differential for the magnetization in a computation target direction of the spatial direction and/or the angular frequency direction. Specifically, the processing circuitry 11 computes the update formula by using the numerical value before update of magnetization, without using the numerical value before update of a partial differential, and computes the numerical value after update of magnetization. Besides, the processing circuitry 11 computes the update formula by using the numerical value before update of a partial differential in the computation target direction, without using the numerical value before update of a partial differential in a non-computation target direction of the spatial direction and/or the angular frequency direction, and computes the numerical value after update of a partial differential in the computation target direction. Hereinafter, the numerical value of the magnetization of the magnetization vector is referred to as “magnetization value”, and the numerical value of the partial differential of the magnetization is referred to as “partial differential value”. As the update formula, use is made of Bloch equations or a developed form thereof. The Bloch equations according to the present embodiment include not only the original Bloch equations, but also a developed form thereof to which a diffusion term by Torrey or a magnetization transfer term by McConnell is added.

By the numerical computation function 112, the processing circuitry 11 may generate data corresponding to a purpose of the magnetic resonance numerical simulation (hereinafter “simulation data”), based on the magnetization value after update and the partial differential value after update in the computation target direction. Examples of the simulation data include a prediction output value of an A/D converter, and an MR image based on the prediction output value. Note that the magnetization value and the spatial partial differential value may be set in the simulation data.

By the output control function 113, the processing circuitry 11 outputs simulation data, such as the magnetization value and partial differential value after update, which are computed by the numerical computation function 112. In one example, the processing circuitry 11 displays the simulation data on the display device 13, stores the simulation data in the storage device 15, or transmits the simulation data to some other computer via the communication device 12.

The communication device 12 is an interface for connection to a magnetic resonance imaging apparatus, a workstation, a PACS (Picture Archiving and Communication System), a HIS (Hospital Information System), an RIS (Radiology Information System), or the like, via a LAN (Local Area Network) or the like. The communication device 12 transmits and receives various data to and from a connection destination.

The display device 13 displays various data in accordance with the output control function 113 of the processing circuitry 11. As the display device 13, use can be made of, as appropriate, a liquid crystal display (LCD), a cathode ray tube (CRT) display, an organic electro-luminescence (EL) display (OELD), a plasma display, or some other freely chosen display. Besides, the display device 13 may be a projector.

The input device 14 accepts various input operations from a user, converts an accepted input operation to an electric signal, and outputs the electric signal to the processing circuitry 11. Specifically, the input device 14 is connected to input devices such as a mouse, a keyboard, a trackball, a switch, a button, a joystick, a touchpad, and a touch panel display. The input device 14 outputs to the processing circuitry 11 an electric signal corresponding to an input operation to the input device 14. In addition, the input device 14 may be an input device provided in some other computer that is connected via a network or the like. The input device 14 may be a speech recognition device that converts a voice signal collected by a microphone into an instruction signal.

The storage device 15 is a storage device that stores various data, such as a ROM (Read Only Memory), a RAM (Random Access Memory), an HDD (Hard Disk Drive), an SSD (Solid State Drive), an integrated circuit storage device, or the like. The storage device 15 stores, for example, a magnetic resonance numerical simulation program or the like. The storage device 15 may be, aside from the above-mentioned storage devices, a portable storage medium such as a CD (Compact Disc), a DVD (Digital Versatile Disc) or a flash memory, or a drive device that reads and writes various information from and to a semiconductor memory element or the like. The storage device 15 may be provided in some other computer that is connected to the magnetic resonance numerical simulation apparatus 1 via a network.

As described above, the magnetic resonance numerical simulation apparatus 1 according to the present embodiment includes the processing circuitry 11. The processing circuitry 11 inputs, in regard to the isochromat, the numerical value before update of magnetization and the numerical value before update of a partial differential for the magnetization in the spatial direction and/or the angular frequency direction. Using a part of the numerical values before update of magnetization and the numerical values before update of partial differentials, the processing circuitry 11 computes the update formula expressing the time-dependent behavior of magnetic resonance, and computes, in regard to the isochromat, the numerical value after update of the magnetization and the numerical value after update of the partial differential in the computation target direction of the spatial direction and/or the angular frequency direction.

Specifically, in the case of computing the magnetization value after update, the processing circuitry 11 uses the magnetization value before update as the part of the numerical values. In other words, the processing circuitry 11 may not use the partial differential value before update as the part of the numerical values. In the case of computing the partial differential value after update in the computation target direction, the processing circuitry 11 uses, as the part of the numerical values, the magnetization value before update and the partial differential value before update in the computation target direction. In other words, the processing circuitry 11 may not use the partial differential value before update in the non-computation target direction as the part of the numerical values. Note that one or a plurality of components can exist as each of the partial differential value in the spatial direction and/or the partial differential value in the angular frequency direction. For example, in regard to the partial differential value in the spatial direction, there can be a plurality of components, such as a partial differential value in a readout gradient magnetic field direction, a partial differential value in a phase encoding gradient magnetic field direction, and a partial differential value in a slice selection gradient magnetic field direction. It is assumed that the partial differential value in the computation target direction designates a part of these components. Similarly, in regard to the partial differential value in the angular frequency direction, there can be a plurality of components. Specifically, in the case of computing the partial differential value after update in the computation target direction, in order to compute the numerical value after update of the partial differential in the computation target direction of the spatial direction and/or angular frequency direction, the processing circuitry 11 does not need to use all of the numerical values of the magnetization value before update, the partial differential value in the computation target direction, and the partial differential value in the non-computation target direction, but may use the magnetization value before update and the partial differential value in the computation target direction.

According to the above-described configuration, the present embodiment can reduce the arithmetic operation amount of the update formula, compared to the case of using all numerical values of the magnetization value and partial differential value before update. Thus, as a result, the computation time and the memory consumption amount can be reduced, and, by extension, the computation efficiency of the magnetic resonance numerical simulation can be improved.

Here, the present embodiment is compared with Non Patent Literature 1 (Latta P, Gruwel MLH, Jellus V, Tomanek B. “Bloch simulations with intra-voxel spin dephasing” Journal of Magnetic Resonance. 2010; 203:44-51). In Non Patent Literature 1, magnetizations at a time of giving minute errors of about 10⁻⁶ to each of directions of x, y and z in Bloch equations are computed, and phases are computed by regarding a magnetization difference for each axis as a differential, and thereby an intra-voxel spin dephasing is simulated. Compared to Non Patent Literature 1, in the present embodiment, without replacing the differential with the difference, the spatial partial differential value is computed. Further, in the present embodiment, by making use of the fact that there is no interaction between spatial partial differentials in different partial differential directions, the update formula is applied to only the components contributing to the computation of numerical values after update. Thereby, in the present embodiment, the numerical values after update can be computed in a short time, without disregarding the accuracy of the result.

Hereinafter, a description is given of an example of the magnetic resonance numerical simulation apparatus 1 according to the present embodiment. Note that a magnetization vector, an update formula, and the like are merely examples, and the present embodiment is not limited to these.

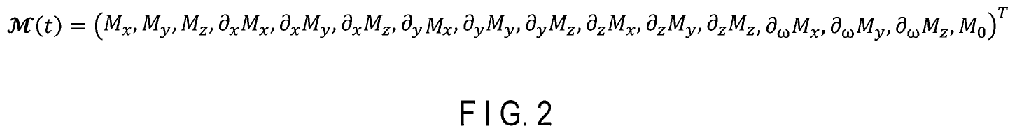

FIG. 2 is a diagram exemplarily illustrating components constituting a magnetization vector M(t) that is a computation target of the magnetic resonance numerical simulation according to the present embodiment. The magnetization vector M(t) illustrated in FIG. 2 represents a vector sum of magnetization moments of an isochromat in a voxel at time t. Specifically, the magnetization vector M(t) can be decomposed into components of Mₓ, M_{y}, M_{z}, ∂ₓMₓ, ∂ₓM_{y}, ∂ₓM_{z}, ∂_{y}Mₓ, ∂_{y}M_{y}, ∂_{y}M_{z}, ∂_{z}Mₓ, ∂_{z}M_{y}, ∂_{z}M_{z}, ∂_{ω}Mₓ, ∂_{ω}M_{y}, ∂_{ω}M_{z}, and M₀. Mₓ, M_{y} and M_{z} represent components in the spatial direction of magnetization. Specifically, Mₓ, M_{y} and M_{z} represent magnetization components in the x direction, y direction and z direction, respectively. ∂ₓMₓ, ∂ₓM_{y}, ∂ₓM_{z}, ∂_{y}Mₓ, ∂_{y}M_{y}, ∂_{y}M_{z}, ∂_{z}Mₓ, ∂_{z}M_{y}, and ∂_{z}M_{z} represent spatial partial differentials for the magnetization in a plurality of spatial directions. Specifically, ∂ₓMₓ, ∂ₓM_{y} and ∂ₓM_{z} represent partial differential components for the magnetization components Mₓ, M_{y} and M_{z} in the x direction. ∂_{y}Mₓ, ∂_{y}M_{y} and ∂_{y}M_{z} represent partial differential components for the magnetization components Mₓ, M_{y} and M_{z} in the y direction. ∂_{z}Mₓ, ∂_{z}M_{y} and ∂_{z}M_{z} represent partial differential components for the magnetization components Mₓ, M_{y} and M_{z} in the z direction. ∂_{ω}Mₓ, ∂_{ω}M_{y} and ∂_{ω}M_{z} represent partial differential components for the magnetization components Mₓ, M_{y} and M_{z} in the angular frequency direction. M₀ represents magnetization of the isochromat in a thermal equilibrium state. T means a transposition.

Note that in the present embodiment, although the x axis, y axis and z axis can be set to be freely chosen directions, it is assumed, for the purpose of convenience of computation, that the x axis is set to be a readout gradient magnetic field direction, the y axis is set to be a phase encoding gradient magnetic field direction, and the z axis is set to be a slice selection gradient magnetic field direction. In addition, partial differential components in the angular frequency direction may be taken into account, or may not be taken into account.

In regard to each of a plurality of voxels set in an examination target model, the processing circuitry 11 applies an update formula to the magnetization vector M(t) before update, and computes a magnetization vector M(t+Δt) after a given time step Δt as a magnetization vector after update. At this time, on the assumption that the magnetic field in each voxel is linear, the processing circuitry 11 computes magnetization at a freely selected position in the voxel by using a spatial partial differential of magnetization. The magnetization after update at a freely selected position in the voxel can be computed by a time differential and a spatial partial differential.

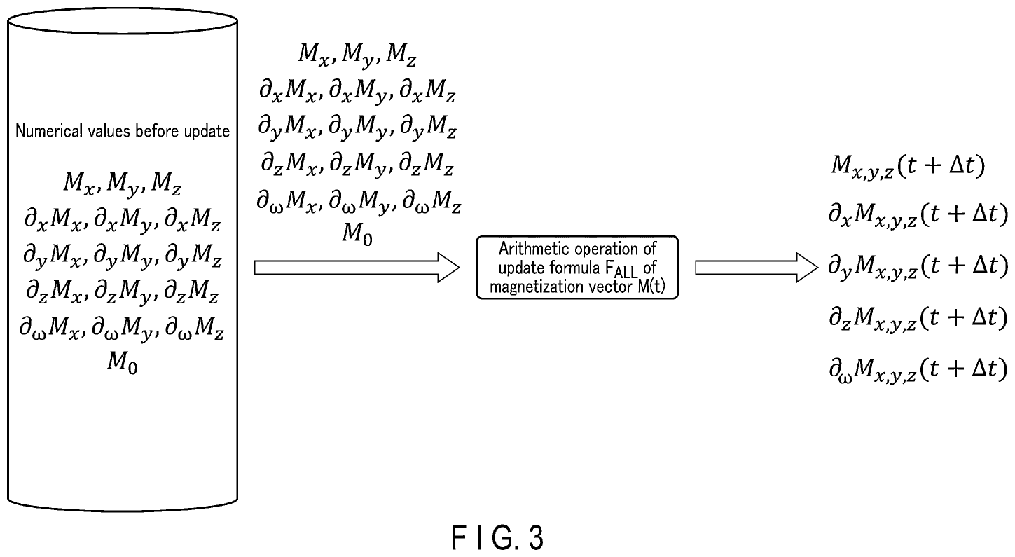

FIG. 3 is a diagram schematically illustrating a computation process of a magnetization vector M(t+Δt) according to a comparative example. As illustrated in FIG. 3, in the comparative example, an arithmetic operation of one update formula F_{ALL} for the magnetization vector M(t) is executed. The update formula F_{ALL} means one computation formula that derives the components Mₓ, M_{y}, M_{z}, ∂ₓMₓ, ∂ₓM_{y}, ∂ₓM_{z}, ∂_{y}Mₓ, ∂_{y}M_{y}, ∂_{y}M_{z}, ∂_{z}Mₓ, ∂_{z}M_{y}, ∂_{z}M_{z}, ∂_{ω}Mₓ, ∂_{ω}M_{y}, and ∂_{ω}M_{z} included in the magnetization vector M(t). In this case, by using all the components Mₓ, M_{y}, M_{z}, ∂ₓMₓ, ∂ₓM_{y}, ∂ₓM_{z}, ∂_{y}Mₓ ∂_{y}M_{y}, ∂_{y}M_{z}, ∂_{z}Mₓ, ∂_{z}M_{y}, ∂_{z}M_{z}, ∂_{ω}Mₓ, ∂_{ω}M_{y}, and ∂_{ω}M_{z}, and M₀, the update formula F_{ALL} is computed, and the magnetization value M_{x, y, z} (t+Δt) after update and the spatial partial differential values ∂ₓM_{x, y, z} (t+Δt), ∂_{y}M_{x, y, z} (t+Δt), and ∂_{z}M_{x, y, z} (t+Δt) after update are computed. Note that M_{x, y, z} (t+Δt) are an expression in which Mₓ (t+Δt), M_{y} (t+Δt) and M_{z} (t+Δt) are abbreviated.

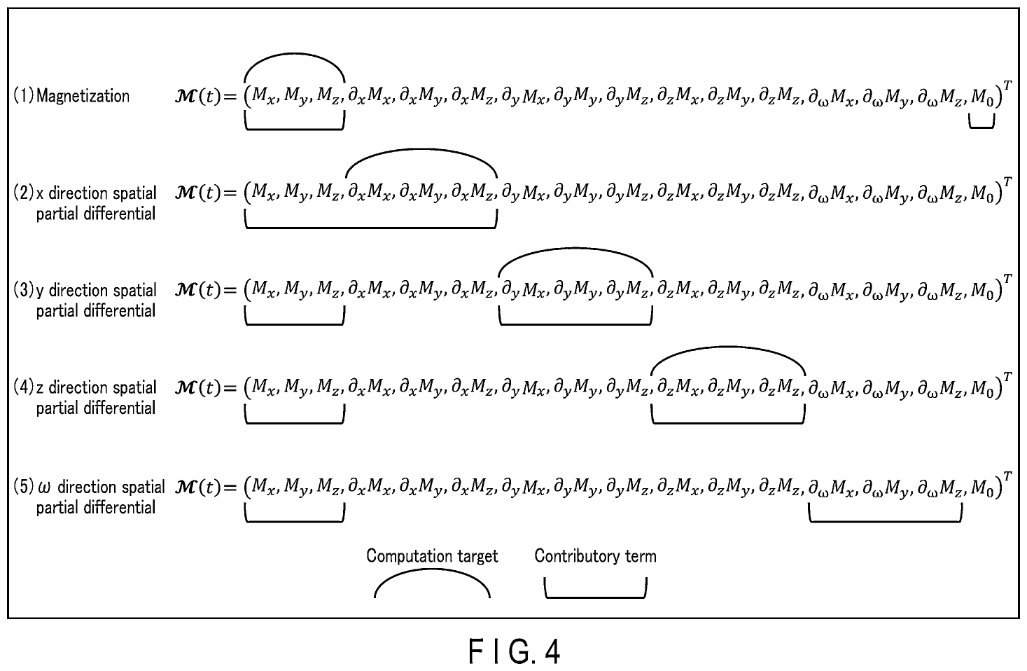

FIG. 4 is a diagram illustrating computation targets and contributory terms relating to the magnetization vector M(t). The computation target means a component to which attention is paid among the components constituting the magnetization vector. As regards the spatial partial differential value, the computation target is determined by the spatial directions (hereinafter, partial differential directions) of partial differentiation, such as the x direction, y direction and z direction. The contributory terms mean components used in order to compute the computation target, in other words, the contributory terms mean components used in the term that is used for computing the computation target in the update formula F_{ALL}. Terms other than the contributory terms (hereinafter “non-contributory terms”) mean components not used in order to compute the computation target, or, in other words, components not included in the term used for the computation of the computation target in the update formula F_{ALL}. As regards the spatial partial differential value, the non-contributory terms mean partial differential directions other than the partial differential direction of the computation target.

As illustrated in part (1) of FIG. 4, in a case where the computation target is magnetization values Mₓ, M_{y} and M_{z}, the contributory terms therefor are Mₓ, M_{y}, M_{z} and M₀, and the non-contributory terms are partial differential values ∂ₓMₓ, ∂ₓM_{y}, ∂ₓM_{z}, ∂_{y}Mₓ, ∂_{y}M_{y}, ∂_{y}M_{z}, ∂_{z}Mₓ, ∂_{z}M_{y}, ∂_{z}M_{z}, ∂_{ω}Mₓ, ∂_{ω}M_{y}, and ∂_{ω}M_{z} in all spatial directions and the angular frequency direction. As illustrated in part (2) of FIG. 4, in a case where the computation target is spatial partial differential values ∂ₓMₓ, ∂ₓM_{y} and ∂ₓM_{z} in the x direction, the contributory terms therefor are Mₓ, M_{y}, M_{z}, ∂ₓMₓ, ∂ₓM_{y} and ∂ₓM_{z}, and the non-contributory terms are partial differential values ∂_{y}Mₓ, ∂_{y}M_{y}, ∂_{y}M_{z}, ∂_{z}Mₓ, ∂_{z}M_{y}, ∂_{z}M_{z}, ∂_{ω}Mₓ, ∂_{ω}M_{y}, ∂_{ω}M_{z}, and M₀ in the y direction, z direction and ω direction. As illustrated in part (3) of FIG. 4, in a case where the computation target is spatial partial differential values ∂_{y}Mₓ, ∂_{y}M_{y} and ∂_{y}M_{z} in the y direction, the contributory terms therefor are Mₓ, M_{y}, M_{z}, ∂_{y}Mₓ, ∂_{y}M_{y} and ∂_{y}M_{z}, and the non-contributory terms are partial differential values ∂ₓMₓ, ∂ₓM_{y}, ∂ₓM_{z}, ∂_{z}Mₓ, ∂_{z}M_{y}, ∂_{z}M_{z}, ∂_{ω}Mₓ, ∂_{ω}M_{y}, ∂_{ω}M_{z}, and M₀ in the x direction, z direction and ω direction. As illustrated in part (4) of FIG. 4, in a case where the computation target is spatial partial differential values ∂_{z}Mₓ, ∂_{z}M_{y} and ∂_{z}M_{z} in the z direction, the contributory terms therefor are Mₓ, M_{y}, M_{z}, ∂_{z}Mₓ, ∂_{z}M_{y} and ∂_{z}M_{z}, and the non-contributory terms are partial differential values ∂ₓMₓ, ∂ₓM_{y}, ∂ₓM_{z}, ∂_{y}Mₓ, ∂_{y}M_{y}, ∂_{y}M_{z}, ∂_{ω}Mₓ, ∂_{ω}M_{y}, ∂_{ω}M_{z}, and M₀ in the x direction, y direction and ω direction. In addition, as illustrated in part (5) of FIG. 4, in a case where the computation target is partial differential values ∂_{ω}Mₓ, ∂_{ω}M_{y} and ∂_{ω}M_{z} in the ω direction, the contributory terms therefor are Mₓ, M_{y}, M_{z}, ∂_{ω}Mₓ, ∂_{ω}M_{y} and ∂_{ω}M_{z}, and the non-contributory terms are spatial partial differential values ∂ₓMₓ, ∂ₓM_{y}, ∂ₓM_{z}, ∂_{y}Mₓ, ∂_{y}M_{y}, ∂_{y}M_{z}, ∂_{z}Mₓ, ∂_{z}M_{y}, ∂_{z}M_{z}, and M₀ in all spatial directions.

Note that, for example, in a case where a Torrey's diffusion term is included in the Bloch equations, the spatial partial differential values ∂ₓMₓ, ∂ₓM_{y}, ∂ₓM_{z}, ∂_{y}Mₓ, ∂_{y}M_{y}, ∂_{y}M_{z}, ∂_{z}Mₓ, ∂_{z}M_{y} and ∂_{z}M_{z} in all spatial directions are added as contributory terms (even if these values are non-contributory terms in Bloch equations) in regard to all computation targets.

As illustrated in parts (1) to (5) of FIG. 4, it is understood that a contributory term and a non-contributory term are present in regard to each of the magnetization component, the partial differential component in the x direction, the partial differential component in the y direction, the partial differential component in the z direction and the partial differential component in the ω direction of the magnetization vector. For example, in order to compute the magnetization value, the partial differential values in all directions may not be used. In another example, in order to compute the spatial partial differential component value in a certain direction, the spatial partial differential component value in another spatial direction may not be used. This can also be described such that there is no interaction between the partial differential components in different spatial directions. Thus, the magnetization component, the partial differential component in the x direction, the partial differential component in the y direction, the partial differential component in the z direction and the partial differential component in the ω direction are separately computed.

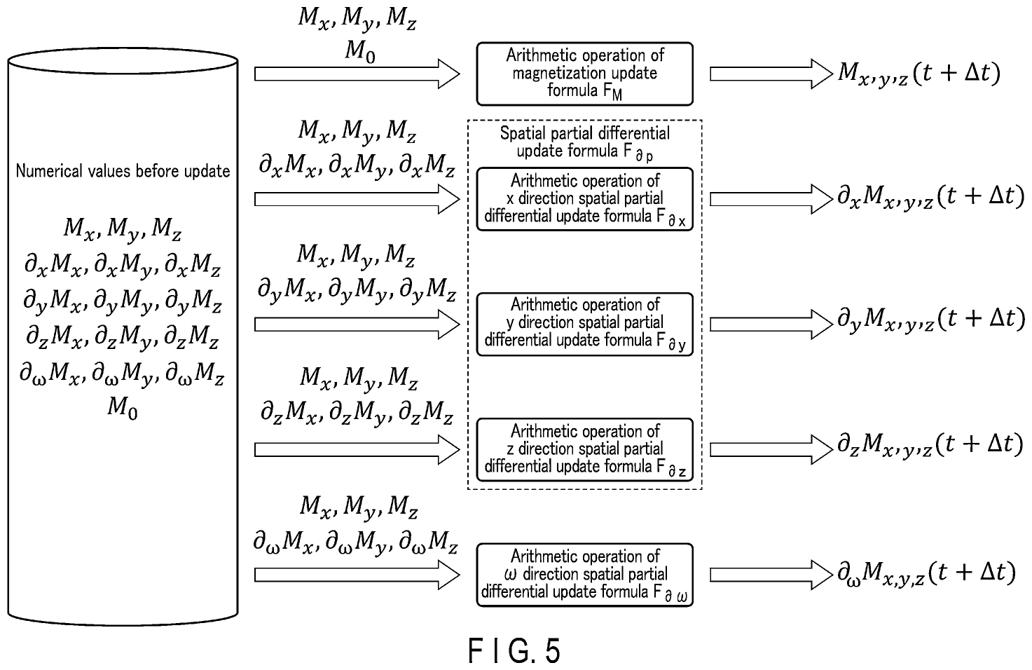

FIG. 5 is a diagram schematically illustrating an arithmetic operation process of an update formula of a magnetization vector according to the first embodiment. As illustrated in FIG. 5, in the first embodiment, the update formula of the magnetization vector is divided into an update formula of the magnetization component (hereinafter “magnetization update formula”) F_{M}, an update formula of the spatial partial differential component (hereinafter “spatial partial differential update formula”) F_{∂p}, and an update formula of the angular frequency partial differential component (hereinafter “angular frequency partial differential update formula” or “ω direction partial differential update formula”) F_{∂ω}. The spatial partial differential update formula F_{∂p} is further divided into an update formula of the spatial partial differential component in the x direction (hereinafter “x direction partial differential update formula”) F_{∂x}, an update formula of the spatial partial differential component in the y direction (hereinafter “y direction partial differential update formula”) F_{∂y}, and an update formula of the spatial partial differential component in the z direction (hereinafter “z direction partial differential update formula”) F_{∂z}.

As illustrated in FIG. 5, in a case of computing the magnetization value M_{x, y, z} (t+Δt), the processing circuitry 11 executes an arithmetic operation of the magnetization update formula F_{M} by using the contributory terms Mₓ, M_{y}, M_{z} and M₀, without using the non-contributory terms ∂ₓMₓ, ∂ₓM_{y}, ∂ₓM_{z}, ∂_{y}Mₓ, ∂_{y}M_{y}, ∂_{y}M_{z}, ∂_{z}Mₓ, ∂_{z}M_{y}, ∂_{z}M_{z}, ∂_{ω}Mₓ, ∂_{ω}M_{y}, and ∂_{ω}M_{z}. In a case of computing the x direction partial differential value ∂ₓM_{x, y, z} (t+Δt), the processing circuitry 11 executes an arithmetic operation of the x direction partial differential update formula F_{∂x} by using the contributory terms Mₓ, M_{y}, M_{z}, ∂ₓMₓ, ∂ₓM_{y} and ∂ₓM_{z}, without using the non-contributory terms ∂_{y}Mₓ, ∂_{y}M_{y}, ∂_{y}M_{z}, ∂_{z}Mₓ, ∂_{z}M_{y}, ∂_{z}M_{z}, ∂_{ω}Mₓ, ∂_{ω}M_{y}, ∂_{ω}M_{z} and M₀. In a case of computing the y direction partial differential value ∂_{y}M_{x, y, z} (t+Δt), the processing circuitry 11 executes an arithmetic operation of the y direction partial differential update formula F_{∂y} by using the contributory terms Mₓ, M_{y}, M_{z}, ∂_{y}Mₓ, ∂_{y}M_{y} and ∂_{y}M_{z}, without using the non-contributory terms ∂ₓMₓ, ∂ₓM_{y}, ∂ₓM_{z}, ∂_{z}Mₓ, ∂_{z}M_{y}, ∂_{z}M_{z}, ∂_{ω}Mₓ, ∂_{ω}M_{y}, ∂_{ω}M_{z} and M₀. In a case of computing the z direction partial differential value ∂_{z}M_{x, y, z} (t+Δt), the processing circuitry 11 executes an arithmetic operation of the z direction partial differential update formula F_{∂z} by using the contributory terms Mₓ, M_{y}, M_{z}, ∂_{z}Mₓ, ∂_{z}M_{y} and ∂_{z}M_{z}, without using the non-contributory terms ∂ₓMₓ, ∂ₓM_{y}, ∂ₓM_{z}, ∂_{y}Mₓ, ∂_{y}M_{y}, ∂_{y}M_{z}, ∂_{ω}Mₓ, ∂_{ω}M_{y}, ∂_{ω}M_{z} and M₀. In a case of computing the ω direction partial differential value ∂_{ω}M_{x, y, z} (t+Δt), the processing circuitry 11 executes an arithmetic operation of the ω direction partial differential update formula F_{∂ω} by using the contributory terms Mₓ, M_{y}, M_{z}, ∂_{ω}Mₓ, ∂_{ω}M_{y} and ∂_{ω}M_{z}, without using the non-contributory terms ∂ₓMₓ, ∂ₓM_{y}, ∂ₓM_{z}, ∂_{y}Mₓ, ∂_{y}M_{y}, ∂_{y}M_{z}, ∂_{z}Mₓ, ∂_{z}M_{y}, ∂_{z}M_{z} and M₀.

As described above, the update formula F_{ALL} according to the first embodiment includes the magnetization update formula F_{M}, the spatial partial differential update formula F_{∂p}, and the angular frequency partial differential update formula F_{∂ω}, which are separated from each other. In order to compute the magnetization value after update, the processing circuitry 11 executes an arithmetic operation of the magnetization update formula F_{M} by referring to only the magnetization value before update. Here, “referring to” means accessing and reading the numerical value before update, which is stored in the storage device 15. In addition, in order to compute the spatial partial differential value after update in the computation target direction, the processing circuitry 11 executes an arithmetic operation of the spatial partial differential update formula F_{∂p} by referring to only the magnetization value and spatial partial differential value in the computation target direction before update. The spatial partial differential update formula F_{∂p} includes the x direction partial differential update formula F_{∂x}, the y direction partial differential update formula F_{∂y}, and the z direction partial differential update formula F_{∂z}, which are separated from each other. In order to compute the x direction partial differential value after update, the processing circuitry 11 executes an arithmetic operation of the x direction partial differential update formula F_{∂x} by referring to only the magnetization value and x direction partial differential value before update. In addition, in order to compute the y direction partial differential value after update, the processing circuitry 11 executes an arithmetic operation of the y direction partial differential update formula F_{∂y} by referring to only the magnetization value and y direction partial differential value before update. Besides, in order to compute the z direction partial differential value after update, the processing circuitry 11 executes an arithmetic operation of the z direction partial differential update formula F_{∂z} by referring to only the magnetization value and z direction partial differential value before update. In order to compute the angular frequency direction partial differential value after update, the processing circuitry 11 executes an arithmetic operation of the angular frequency partial differential update formula Fa, by referring to only the magnetization value and angular frequency direction partial differential value before update.

In this manner, by separating the update formulae relating to the components that do not interact, it becomes unnecessary to refer to non-contributory terms at a time of executing an arithmetic operation of the update formula relating to the computation target component. By executing an arithmetic operation of the update formula relating to the computation target component by referring to the contributory terms, without referring to the non-contributory terms, the computation time and computation load of the update formula can be reduced, compared to the case of calculating the update formula F_{ALL} of the magnetization vector as illustrated in FIG. 3.

Next, the processing procedure of the magnetic resonance numerical simulation according to the first embodiment is explained by describing Example 1 and Example 2 separately.

### Example 1

The Bloch equations representing a time-dependent behavior of magnetic resonance are expressed by equation (1) below. Note that a diffusion term is not considered in the present embodiment.

$$\frac{dM}{dt} = γ ( M ( t ) \times B ( t ) ) + ( \begin{matrix}- 1 / {T}_{2} & 0 & 0 \\ 0 & - 1 / {T}_{2} & 0 \\ 0 & 0 & - 1 / {T}_{1}\end{matrix} ) ( \begin{matrix}{M}_{x} ( t ) \\ {M}_{y} ( t ) \\ {M}_{z} ( t )\end{matrix} ) + ( \begin{matrix}0 \\ 0 \\ {M}_{0} / {T}_{1}\end{matrix} ) \qquad ( 1 )$$

M is a magnetization vector, B is an effective magnetic field vector, and y is a gyromagnetic ratio. T₁ is a longitudinal relaxation time, and T₂ is a transverse relaxation time. The x, y and z components of the Bloch equations, if developed, are expressed by equations (2), (3) and (4) below. Equations (2), (3) and (4) correspond to magnetization update formulae in the x direction, y direction and z direction.

$$\frac{\partial {M}_{x} ( t )}{\partial t} = γ ( {M}_{y} ( t ) {B}_{z} ( t ) - {M}_{z} ( t ) {B}_{y} ( t ) ) - \frac{1}{{T}_{2}} {M}_{x} ( t ) \qquad ( 2 )$$

$$\frac{\partial {M}_{y} ( t )}{\partial t} = γ ( {M}_{z} ( t ) {B}_{x} ( t ) - {M}_{x} ( t ) {B}_{z} ( t ) ) - \frac{1}{{T}_{2}} {M}_{y} ( t ) \qquad ( 3 )$$

$$\frac{\partial {M}_{z} ( t )}{\partial t} = γ ( {M}_{x} ( t ) {B}_{y} ( t ) - {M}_{y} ( t ) {B}_{x} ( t ) ) - \frac{1}{{T}_{1}} ( {M}_{z} ( t ) - {M}_{0} ) \qquad ( 4 )$$

As in the above equations (2), (3) and (4), the computation formula of the magnetization value includes the term relating to magnetization and the term relating to M₀, but does not include a term relating to the spatial partial differential. In this manner, since there is no need to use the spatial partial differential value at the time of computing the magnetization value, the magnetization update formula and the spatial partial differential update formula can be separated. By separating the formulae, compared to the case of not separating the formulae, the computation time of the magnetization value after update can be reduced.

Next, the formula of the spatial direction partial differential of the Bloch equations is calculated. It is assumed that the differential in each of the x, y and z directions and t direction is continuous in a minute time. However, a position at which a result t with a magnetic field being a piecewise constant is discontinuous is ignored. In addition, in regard to a small voxel corresponding to one isochromat, a static magnetic field, including a chemical shift, is constant. Assuming p∈{x, y, z}, the spatial partial differentials of the Mₓ(t), M_{y}(t) and M_{z}(t) are expressed by equations (5), (6) and (7) below.

$$\frac{\partial }{\partial t} \frac{\partial {M}_{x} ( t )}{\partial p} = γ ( \frac{\partial {M}_{y} ( t )}{\partial p} {B}_{z} ( t ) - \frac{\partial {M}_{z} ( t )}{\partial p} {B}_{y} ( t ) ) + γ ( {M}_{y} ( t ) \frac{\partial {B}_{z} ( t )}{\partial p} - {M}_{z} ( t ) \frac{\partial {B}_{y} ( t )}{\partial p} ) - \frac{1}{{T}_{2}} \frac{\partial {M}_{x} ( t )}{\partial p} \qquad ( 5 )$$

$$\frac{\partial }{\partial t} \frac{\partial {M}_{y} ( t )}{\partial p} = γ ( \frac{\partial {M}_{z} ( t )}{\partial p} {B}_{x} ( t ) - \frac{\partial {M}_{x} ( t )}{\partial p} {B}_{z} ( t ) ) + γ ( {M}_{z} ( t ) \frac{\partial {B}_{x} ( t )}{\partial p} - {M}_{x} ( t ) \frac{\partial {B}_{z} ( t )}{\partial p} ) - \frac{1}{{T}_{2}} \frac{\partial {M}_{y} ( t )}{\partial p} \qquad ( 6 )$$

$$\frac{\partial }{\partial t} \frac{\partial {M}_{z} ( t )}{\partial p} = γ ( \frac{\partial {M}_{x} ( t )}{\partial p} {B}_{y} ( t ) - \frac{\partial {M}_{y} ( t )}{\partial p} {B}_{x} ( t ) ) + γ ( {M}_{x} ( t ) \frac{\partial {B}_{y} ( t )}{\partial p} - {M}_{y} ( t ) \frac{\partial {B}_{x} ( t )}{\partial p} ) - \frac{1}{{T}_{1}} \frac{\partial {M}_{z} ( t )}{\partial p} \qquad ( 7 )$$

As in the above equations (5), (6) and (7), the computation equation of the spatial partial differential value in the computation target direction p includes the partial differential term in this direction p, but does not include the partial differential term in another direction q (≠p). For example, in a case of p=x in equations (5), (6) and (7), only terms relating to the computation target direction x are present in equations (5), (6) and (7), and terms including a non-computation target direction y and/or z do not present. Specifically, since there is no need to use the spatial partial differential value in the non-computation target direction at the time of computing the spatial partial differential value in the computation target direction, the spatial partial differential formulas can be separated in regard to each computation target direction. Thus, compared to the case of not separating the formulas, the time of computing the spatial partial differential value after update can be reduced.

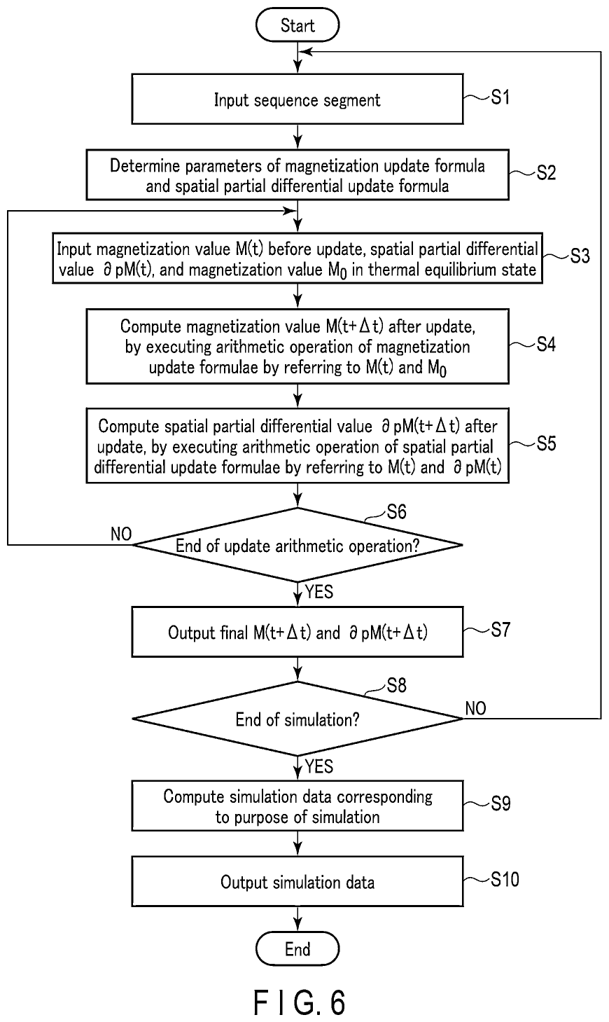

FIG. 6 is a diagram exemplarily illustrating a processing procedure of a magnetic resonance numerical simulation according to Example 1. It is assumed that at a start time point in FIG. 6, a pulse sequence of a computation target is already set. The pulse sequence used in the present embodiment is not particularly limited, and any kind of pulse sequence is applicable. Hereinafter, by way of example, the pulse sequence used in the present embodiment is assumed to be a pulse sequence by a spin echo method. Note that in the example illustrated in FIG. 6, the angular frequency direction partial differential is not considered.

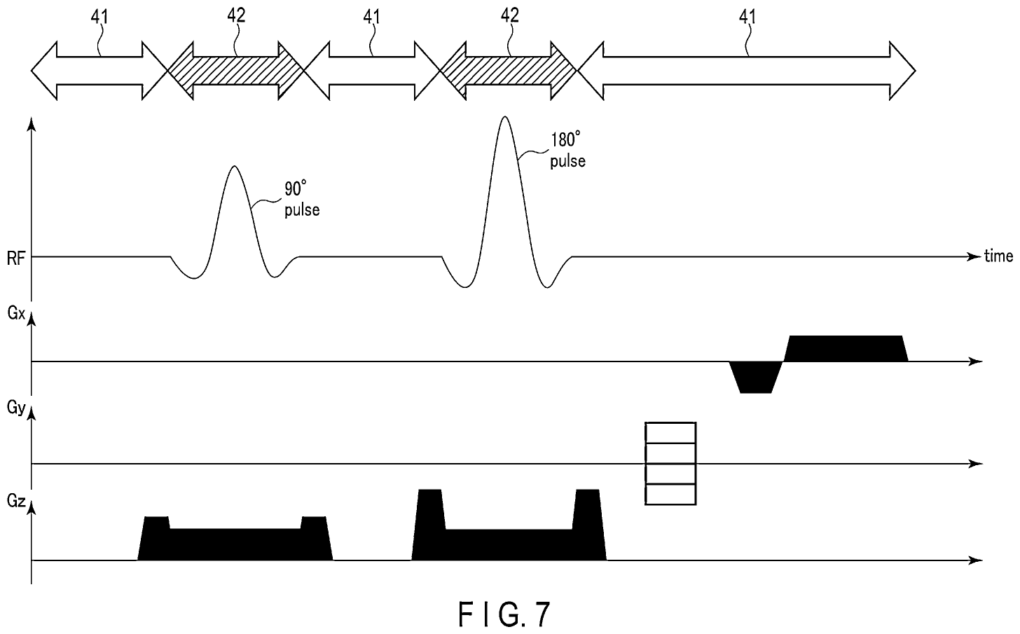

FIG. 7 is a diagram illustrating an example of a pulse sequence by a spin echo method. In FIG. 7, a timeline of “RF” indicates a sequence of RF pulses that are applied by an RF transmitter coil that is driven in accordance with a driving signal from transmission circuitry. A timeline of “Gx” indicates a sequence of readout gradient magnetic field pulses that are applied by a Gx coil that is driven in accordance with a driving signal from a gradient magnetic field power supply. A timeline of “Gy” indicates a sequence of phase encoding gradient magnetic field pulses that are applied by a Gy coil that is driven in accordance with a driving signal from the gradient magnetic field power supply. A timeline of “Gz” indicates a sequence of slice selection gradient magnetic field pulses that are applied by a Gz coil that is driven in accordance with a driving signal from the gradient magnetic field power supply. As illustrated in FIG. 7, the pulse sequence can be divided into a nonapplication period 41 that is a period in which the RF pulse is not applied, and an application period 42 that is a period in which the RF pulse is applied.

As illustrated in FIG. 7, in the spin echo method, a first slice selection gradient magnetic field pulse is applied along with the application of a 90° pulse, a second slice selection gradient magnetic field pulse is applied along with the application of a 180° pulse, and a phase encoding pulse of a given magnetic field gradient is applied. An echo signal (not illustrated) occurs in such a manner that a peak of a signal value comes after the passage of an echo time from the application of the 90° pulse. The echo signal is received by a receiver coil, and the received analog echo signal is converted to digital k-space data by an A/D converter (ADC: Analog digital converter). The k-space data is an example of a prediction output value of the A/D converter. At the time of reception of the echo signal, a readout gradient magnetic field pulse is applied. A time from the application of the 90° pulse to the application of the readout gradient magnetic field pulse is a TR (time of repetition). The above-described pulse sequence is repeated over a given number of phase encoding steps.

As illustrated in FIG. 6, by implementing the input function 111, the processing circuitry 11 inputs a sequence segment (step S1). The sequence segment is a part of a pulse sequence that is divided by a freely selected rule. The pulse sequence may be divided at predetermined time intervals, or may be divided in accordance with pulse kinds such as “RF”, “Gx”, “Gy” and “Gz”, or may be divided in units of a combination thereof.

If step S1 is executed, the processing circuitry 11 determines, by implementing the numerical computation function 112, parameters (hereinafter “update formula parameters”) of the magnetization update formula and the spatial partial differential update formula (step S2). In step S2, the processing circuitry 11 determines the update formula parameters by utilizing the sequence segment that is input in step S1. The update formula parameters are determined for each of all isochromats disposed in a model that is an examination target. Examples of the update formula parameters include a T1 value, a T2 value, and B value included in the update formulae.

If step S2 is executed, the processing circuitry 11 inputs, by implementing the input function 111, a magnetization value M(t) before update, a spatial partial differential value ∂ₚM(t), and a magnetization value M₀ in a thermal equilibrium state (step S3). In the first update arithmetic operation, freely selected initial values are input for M(t) and ∂ₚM(t) before update. In the second and following update arithmetic operations, as regards M(t) and ∂ₚM(t), M(t+Δt) and ∂ₚM(t+Δt) obtained in the previous update arithmetic operation are input. As regards the magnetization value M₀, a freely selected value may be input. It is assumed that M(t) and ∂ₚM(t) before update and the magnetization value M₀ are stored in the storage device 15 before step S2. The processing circuitry 11 reads out M(t) and ∂ₚM(t) before update and the magnetization value M₀ from the storage device 15, and inputs them to the processing circuitry 11 itself.

If step S3 is executed, the processing circuitry 11 computes, by implementing the numerical computation function 112, a magnetization value M(t+Δt) after update, by executing an arithmetic operation of the magnetization update formulae (2), (3) and (4) by referring to only the magnetization values M(t) and M₀ (step S4). At this time, the processing circuitry 11 does not need to refer to the spatial partial differential value ∂ₚM(t). Thereby, the computation speed of the magnetization value M(t+Δt) is increased. The computed magnetization value M(t+Δt) after update is stored in the storage device 15. An arithmetic operation of the magnetization update formula can be executed by using the Runge-Kutta method or the like.

If step S4 is executed, the processing circuitry 11 computes, by implementing the numerical computation function 112, a spatial partial differential value ∂ₚM(t+Δt) after update, by executing an arithmetic operation of the spatial partial differential update formulae (5), (6) and (7) by referring to only the magnetization values M(t) and ∂ₚM(t) (step S5). In step S5, the processing circuitry 11 executes an arithmetic operation of the spatial partial differential update formulae (5), (6) and (7) in regard to the computation target direction p by sequentially changing the computation target direction p to the x direction, y direction and z direction, and computes the spatial partial differential value ∂ₚM(t+Δt) of the computation target direction p. At this time, the processing circuitry 11 does not need to refer to the spatial partial differential value ∂_{q}M(t) of a non-computation target direction q. Thereby, the computation speed of each spatial partial differential value ∂ₚM(t+Δt) is increased. The computed spatial partial differential value ∂ₚM(t+Δt) after update is stored in the storage device 15. An arithmetic operation of the spatial partial differential update formula can be executed by using the Runge-kutta method or the like.

Steps S3 to S5 are executed for all voxels of the examination target model. In addition, in regard to each voxel, on the assumption that a magnetic field in the voxel is linear, the processing circuitry 11 computes the magnetization value at a freely selected position in the voxel by using the spatial partial differential values.

If step S5 is executed, the processing circuitry 11 determines whether or not to end the update arithmetic operation, by implementing the numerical computation function 112 (step S6). If a predetermined update ending condition is satisfied, it is determined that the update arithmetic operation is ended. The update ending condition may be set to be, for example, a condition that the number of times of update has reached a predetermined value. If it is determined that the update arithmetic operation is not ended (step S6: NO), the processing circuitry 11 repeats the process from steps S3 to S6 for the next timing step, until it is determined in step S6 that the update arithmetic operation is ended.

If it is determined that the update arithmetic operation is ended (step S6: YES), the processing circuitry 11 outputs, by implementing the output function 113, the magnetization value M(t+Δt) and spatial partial differential value ∂ₚM(t+Δt) at the last time of the repetition (step S7).

If step S7 is executed, the processing circuitry 11 determines whether or not to end the simulation, by implementing the numerical computation function 112 (step S8). If a predetermined simulation ending condition is satisfied, it is determined that the simulation is ended. The simulation ending condition may be set to be, for example, a condition that processing is completely executed for all sequence segments included in the pulse sequence of the computation target. If it is determined that the simulation ending condition is not satisfied (step S8: NO), the processing circuitry 11 goes to step S1, and inputs the next sequence segment by implementing the input function 111. Then, the processing circuitry 11 executes steps S2 to S8 for the sequence segment, and repeats steps S1 to S8 until it is determined that the simulation ending condition is satisfied. Thereby, the magnetization vector M(t) at predetermined time intervals, in regard to each voxel included in the examination target model by the pulse sequence, and in regard to each isochromat, is obtained.

Then, if it is determined that the simulation ending condition is satisfied (step S8: YES), the processing circuitry 11 computes simulation data corresponding to a purpose of simulation, by implementing the numerical computation function 112 (step S9). The simulation data may be set to be the magnetization vector M(t), an IQ signal, and an MR image. The IQ signal means k-space data collected by the ADC. The IQ signal means a combination of an x component ΣM_{X} and a y component ΣM_{Y} of a sum ΣM of a plurality of magnetization vectors M(T) corresponding to a plurality of isochromats. The MR image is generated by applying a reconstruction arithmetic operation, such as Fourier transform, to the IQ signal.

If step S9 is executed, the processing circuitry 11 outputs the simulation data that was output in step S9, by implementing the output function 113 (step S10). The processing circuitry 11 can output the simulation data to a freely selected output destination such as the communication device 12, display device 13, storage device 15, or the like.

By the above, the magnetic resonance numerical simulation according to Example 1 is terminated.

### Example 2

Next, a magnetic resonance numerical simulation according to Example 2 is described.

It is assumed that a magnetization update formula, a spatial partial differential update formula, and an angular frequency partial differential update formula include a rotation term and a relaxation term. By implementing the numerical computation function 112, the processing circuitry 11 according to Example 2 computes a magnetization rotation term value by executing an arithmetic operation of the rotation term of the magnetization update formula by referring to the magnetization value before update, and computes a magnetization value after update by applying the relaxation term of the magnetization update formula to the magnetization rotation term value. Similarly, by implementing the numerical computation function 112, the processing circuitry 11 computes a partial differential rotation term value by executing an arithmetic operation of the rotation term of the spatial partial differential update formula and/or angular frequency partial differential update formula by referring to the magnetization value before update and the partial differential value in the computation target direction, and computes a partial differential value after update in the computation target direction by applying the relaxation term of the spatial partial differential update formula to the partial differential rotation term value.

The spatial partial differential update formula includes a first term that depends on an effective magnetic field vector component in an orthogonal direction to a slice selection gradient magnetic field direction, a second term that depends on an effective magnetic field vector component in the slice selection gradient magnetic field direction, and a third term that does not depend on the effective magnetic field vector components, the first term, second term and third term being separated from each other. In order to compute a spatial partial differential value after update in the computation target direction, the processing circuitry 11 according to Example 2, with the implementation of the numerical computation function 112, computes a first rotation term value executing an arithmetic operation of the rotation term in the first term by referring to the magnetization value before update and the spatial partial differential value in the computation target direction, computes a second rotation term value by executing an arithmetic operation of the rotation term in the second term by referring to the magnetization value before update and the spatial partial differential value in the computation target direction, and computes a third rotation term value by executing an arithmetic operation of the rotation term in the third term by referring to the magnetization value before update and the spatial partial differential value in the computation target direction. Then, the processing circuitry 11 computes the spatial partial differential value after update in the computation target direction by applying the relaxation term of the spatial partial differential update formula to an addition value of the first rotation term value, second rotation term value and third rotation term value.

To begin with, one example of an update method according to Example 2 is concretely described. Note that solutions of all differential equations indicated below can also be computed in the form of repetitive update in units of a minute time, by using, for example, a Newton method or Runge-Kutta method, and all equations indicating update methods based on differential equations are examples of the solution.

With respect to a minute time in connection with the spatial partial differential of the Block equations indicated in the above equations (5), (6) and (7), update is approximately executed with use of variable separation.

If consideration is given to sequential update with division into a term depending on Bₓ(t) and B_{y}(t), a term depending on B_{z}(t) and other terms, equation (5) representing the spatial partial differential of an Mₓ component in a minute time can be, for example, separated into equations (8), (9) and (10) below. Note that equations for an M_{y} component and an M_{z} component can similarly be generated.

$$\frac{\partial }{\partial t} \frac{\partial {M}_{x} ( t )}{\partial p} = - γ ( \frac{\partial {M}_{z} ( t )}{\partial p} {B}_{y} ( t ) + {M}_{z} ( t ) \frac{\partial {B}_{y} ( t )}{\partial p} ) \qquad ( 8 )$$

$$\frac{\partial }{\partial t} \frac{\partial {M}_{x} ( t )}{\partial p} = γ ( \frac{\partial {M}_{y} ( t )}{\partial p} {B}_{z} ( t ) + {M}_{y} ( t ) \frac{\partial {B}_{z} ( t )}{\partial p} ) \qquad ( 9 )$$

$$\frac{\partial }{\partial t} \frac{\partial {M}_{x} ( t )}{\partial p} = - \frac{1}{{T}_{2}} \frac{\partial {M}_{x} ( t )}{\partial p} \qquad ( 10 )$$

If spatial fluctuations ∂Bₓ(t)/∂ₚ and ∂B_{y}(t)/∂ₚ of RF pulses are zero, equation (11) below is expressed. This differential equation represents a rotation, and can be updated by using the Rodrigues' rotation formula. The same applies to the M_{y} component and M_{z} component. The spatial partial differential update formula based on equation (8) or equation (11) is the term depending on Bₓ(t) and B_{y}(t), and is an example of the above-described “first term that depends on an effective magnetic field vector component in an orthogonal direction to a slice selection gradient magnetic field direction”. Hereinafter, this spatial partial differential update formula is referred to as a B_{xy}-dependent spatial partial differential update formula.

$$\frac{\partial }{\partial t} \frac{\partial {M}_{x} ( t )}{\partial p} = - γ \frac{\partial {M}_{z} ( t )}{\partial p} {B}_{y} ( t ) \qquad ( 11 )$$

Equation (11) can be updated by a similar equation to the update formula described in Non Patent Literature 2 (Hidenori Takeshima. “A Fast and Practical Computation Method for Magnetic Resonance Simulators” Magnetic Resonance in Medicine, DOI: 10.1002/mrm.29646) based on the Rodrigues' rotation formula in which relaxation is ignored in regard to equation (2), by computing a rotation matrix of 3×3 corresponding to magnetic fields Bₓ, B_{y} and B_{z} in regard to a vector in which ∂Mₓ, ∂M_{y}, and ∂M_{z} are put together, and by multiplying the rotation matrix.

The spatial partial differential update formula based on equations (9) and (10) relating to the Mₓ component and M_{y} component is expressed by equation (12) in regard to a minute time. Note that B_{z}(t) bar in equation (12) means a value in a case where B_{z}(t) that fluctuates in a minute time Δt is regarded as a specific fixed value. The spatial partial differential update formula based on equations (9) and (10) relating to the M_{z} component is expressed by equation (13) in regard to the minute time.

$$\frac{\partial }{\partial p} {M}_{xy} ( t + Δ t ) = exp ( - \frac{Δ t}{T 2} ) ( \frac{\partial }{\partial p} {M}_{xy} ( t ) exp ( i \overline{{B}_{z} ( t )} ) + {M}_{xy} ( {t}_{0} ) \frac{\partial }{\partial p} exp ( i \overline{{B}_{z} ( t )} ) ) \qquad ( 12 )$$

$$\frac{\partial }{\partial p} {M}_{z} ( t + Δ t ) = exp ( - \frac{Δ t}{T 1} ) \frac{\partial }{\partial p} {M}_{z} ( t ) \qquad ( 13 )$$

Here, M_{xy}=Mₓ+iM_{y} is assumed. However, in the absence of equation (8), if B_{z}(t) is given by a linear expression relating to x, y, z and w, the update formula relating to M_{xy} can be applied even in the case of not being the minute time. In addition, the update formula relating to M_{z} is applicable even in the case of not being the minute time.

The spatial partial differential update formula expressed by equation (12) is the term depending on B_{z}(t), and is an example of the above-described “second term that depends on an effective magnetic field vector component in a slice selection gradient magnetic field direction”. Hereinafter, the spatial partial differential update formula is referred to as a B_{z}-dependent spatial partial differential update formula. The spatial partial differential update formula expressed by equation (13) is the term that does not depend on Bₓ(t), B_{y}(t) and B_{z}(t), and is an example of the above described “third term that does not depend on the effective magnetic field vector components”. Hereinafter, this spatial partial differential update formula is referred to as a B-non-dependent spatial partial differential update formula.

The update formula of the magnetization vector, if expressed by using the Rodrigues' rotation formula, can be expressed by equation (14) below. Equation (14) corresponds to equation (5) of Non Patent Literature 3 (Thies H. Jochimsen, Andreas Schafer, Roland Bammer, Michael E. Moseley, “Efficient simulation of magnetic resonance imaging with Bloch-Torrey equations using intra-voxel magnetization gradients” Journal of Magnetic Resonance, 2006; 180:29-38).

$$M ( t + Δ t ) = {Rot}_{z} ( {θ}_{g} ) {Rot}_{z} ( {θ}_{i} ) {R}_{relax} {R}_{RF} M ( t ) \qquad ( 14 )$$

The magnetization vector M(t) in the right side of equation (14) represents the magnetization vector of the isochromat included in a region at a position r at a time t, among a plurality of hydrogen atoms disposed in the model that is the examination target in the magnetic resonance numerical simulation. R_{RF} in the right side of equation (14) indicates a rotation term in regard to the z axis and x axis due to the application an RF pulse that causes a flip angle α in a time interval Δt. Specifically, the rotation term R_{RF} indicates the influence of rotation upon the magnetization vector M(t). Rᵣₑₗₐₓ in the right side of equation (14) is a relaxation term indicating the influence of magnetic relaxation upon the magnetization vector M(t) in the time interval Δt. Rot_{z}(θ) in the right side of equation (14) indicates a rotation term in regard to the z axis relating to an angle θ. Here, θ_{g} is an angle relating to an integral value of a gradient magnetic field over the time interval Δt. In addition, θᵢ indicates an angle due to non-uniformity of a static magnetic field over the time interval Δt.

B_{y} executing a spatial partial differential of equation (14) in each of the x direction, y direction and z direction, it is possible to obtain a spatial partial differential update formula (a spatial partial differential update formula of a Rodrigues' rotation formula version) in each of the x direction, y direction and z direction corresponding to equations (5), (6) and (7). By applying variable separation to the x direction partial differential update formula, y direction partial differential update formula and z direction partial differential update formula of Rodrigues' rotation formula versions, it is possible to obtain a Rodrigues' rotation formula version of a B_{xy}-dependent spatial partial differential update formula based on equation (8) or equation (11), a Rodrigues' rotation formula version of a B_{z}-dependent spatial partial differential update formula expressed by equation (12), and a Rodrigues' rotation formula version of a B-non-dependent spatial partial differential update formula expressed by equation (13).

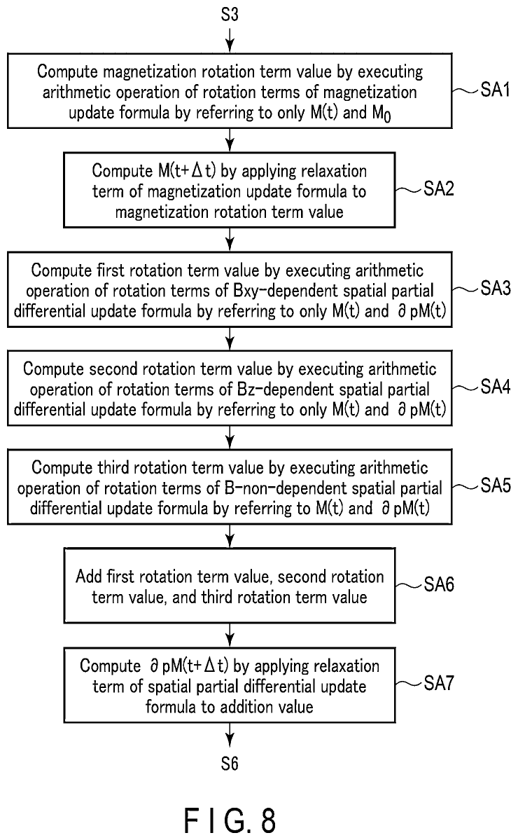

FIG. 8 is a diagram exemplarily illustrating a processing procedure of the magnetic resonance numerical simulation according to Example 2 of the first embodiment. FIG. 8 illustrates a process from step S3 to step S6 of FIG. 6. Each process from step SA1 to step SA6 is executed by the numerical computation function 112. Note that in the example illustrated in FIG. 8, the angular frequency direction partial differential is not taken into account.

If step S3 is executed, the processing circuitry 11 computes a magnetization rotation term value by executing an arithmetic operation of rotation terms Rot_{z} (θ_{g}), Rot_{z} (θᵢ) and R_{RF} of the magnetization update formula by referring to only M(t) and M₀ (step SA1). B_{y} referring to only M(t) and M₀, it is possible to efficiently execute an arithmetic operation of rotation terms Rot_{z}(θ_{g}), Rot_{z}(θᵢ) and R_{RF}.

If step SA1 is executed, the processing circuitry 11 computes a magnetization value M(t+Δt) after update, by applying the relaxation term Rᵣₑₗₐₓ of the magnetization update formula to the magnetization rotation term value computed in step SA1 (step SA2). The magnetization value M(t+Δt) after update is stored in the storage device 15.

If step SA2 is executed, the processing circuitry 11 computes a first rotation term value by executing an arithmetic operation of the rotation terms Rot_{z}(θ_{g}), Rot_{z}(θᵢ) and R_{RF} of the B_{xy}-dependent spatial partial differential update formula by referring to only M(t) and ∂ₚM(t) (step SA3). B_{y} referring to only M(t) and ∂ₚM(t), it is possible to efficiently execute an arithmetic operation of the rotation terms Rot_{z} (θ_{g}), Rot_{z} (θᵢ) and R_{RF} of the B_{xy}-dependent spatial partial differential update formula.

If step SA3 is executed, the processing circuitry 11 computes a second rotation term value by executing an arithmetic operation of the rotation terms Rot_{z}(θ_{g}), Rot_{z}(θᵢ) and R_{RF} of the B_{z}-dependent spatial partial differential update formula by referring to only M(t) and ∂ₚM(t) (step SA4). By referring to only M(t) and ∂ₚM(t), it is possible to efficiently execute an arithmetic operation of the rotation terms Rot_{z}(θ_{g}), Rot_{z}(θᵢ) and R_{RF} of the B_{z}-dependent spatial partial differential update formula. Note that in a case where B_{z}(t) bar has not yet been computed, the arithmetic operation of the rotation terms Rot_{z}(θ_{g}), Rot_{z}(θᵢ) and R_{RF} may be executed after the B_{z}(t) bar is computed.

If step SA4 is executed, the processing circuitry 11 computes a third rotation term value by executing an arithmetic operation of the rotation terms Rot_{z}(θ_{g}), Rot_{z}(θᵢ) and R_{RF} of the B-non-dependent spatial partial differential update formula by referring to only M(t) and ∂ₚM(t) (step SA5). By referring to only M(t) and ∂ₚM(t), it is possible to efficiently execute an arithmetic operation of the rotation terms Rot_{z}(θ_{g}), Rot_{z}(θᵢ) and R_{RF} of the B-non-dependent spatial partial differential update formula.

If step SA5 is executed, the processing circuitry 11 adds the first rotation term value computed in step SA3, the second rotation term value computed in step SA4, and the third rotation term value computed in step SA5 (step SA6). By step SA6, an addition value of the first rotation term value, second rotation term value and third rotation term value is computed.

If step SA6 is executed, the processing circuitry 11 computes a spatial partial differential value ∂ₚM(t+Δt) after update, by applying the relaxation term Rᵣₑₗₐₓ of the partial differential update formula to the addition value obtained in step SA6 (step SA7). The spatial partial differential value ∂ₚM(t+Δt) after update is stored in the storage device 15.

If step SA6 is executed, step S6 illustrated in FIG. 6 is executed.

As described above, according to Example 2, also in the update formula described by using the Rodrigues' rotation formula, the magnetization update formula, the spatial partial differential update formula, and the angular frequency partial differential update formula are separated, and the magnetization value and the spatial partial differential value can efficiently be computed by using the contributory term, without using the non-contributory term. In addition, also in the spatial partial differential update formula, since the spatial partial differential update formula can be separated in regard to each of computation target directions, the spatial partial differential value in each computation target direction can efficiently be computed by using the contributory term, without using the non-contributory term.

Note that the order of processes of steps SA3, SA4 and SAS is not limited to this order, and may be executed in any order. In addition, it is not always necessary to execute an arithmetic operation of all of the B_{xy}-dependent spatial partial differential update formula (first term), the B_{z}-dependent spatial partial differential update formula (second term) and the B-non-dependent spatial partial differential update formula (third term), and the target of the arithmetic operation may be appropriately selected where necessary. For example, the processing circuitry 11 may execute an arithmetic operation of the first term, second term and third term in the application period of the RF pulse, and may execute an arithmetic operation of the second term and third term in the nonapplication period of the RF pulse. In another example, the processing circuitry 11 may execute an arithmetic operation of the first term, second term and third term both in the application period of the RF pulse and in the nonapplication period of the RF pulse.

In addition, in the case of simulating ADC sampling by using the obtained partial differentials in the x, y and z directions, for example, in accordance with the method described in Non Patent Literature 3, a model in which molecules are uniformly disposed in a unit rectangular parallelepiped is used, and, by using M(t), ∂ₓM(t) and ∂_{y}M(t), an angle (∂/∂ₚ)φ is computed by equation (16) of Non Patent Literature 3, and, by multiplying an integral value of a sinc function thereof, the spatial fluctuation of the magnetic field can be reflected on the sampling value. In addition, in the case of simulating T₂-star decay by using the partial differential of the ω direction, the method described in Non Patent Literature 3 (molecules are uniformly disposed only in a specific frequency region) may be used. For example, in another method, use may be made of a model in which molecules are disposed with a probability with which T₂-star decay corresponds to a Lorentz distribution in regard to frequency, and the partial differential of the ω direction may be multiplied by exp{(−1/T₂′)·(∂/∂ₚ)φ}. T₂′ indicates a difference between T₂-star decay (T₂*) and T₂ decay due to non-uniformity of the magnetic field, and is given by 1/T₂′=(1/T₂*)−(1/T₂).

### Second Embodiment

Processing circuitry 11 according to a second embodiment uses a combined transition matrix as an update formula describing a time-dependent behavior of magnetic resonance. The combined transition matrix is a matrix in which a K number (K≥2) of transition matrices T(t+Δtₖ₋₁) describing a time-dependent behavior of magnetization and a time-dependent behavior of a partial differential for each of time steps are combined. Here, k is a natural number of one or more. A combined transition matrix T_{combined}, in which the K transition matrices T(t), T(t+Δt₁), . . . , T(t+Δtₖ₋₁) are combined, can be expressed by equation (15) below. Here, Δtₖ represents a time interval from kt to (k+1)t.

$${T}_{combined} = T ( t + Δ {t}_{K - 1} ) … T ( t + Δ {t}_{1} ) T ( t ) \qquad ( 15 )$$

The update formula of the magnetization vector M(t) using the combined transition matrix T_{combined} can be expressed by equation (16) below.

$$ℳ ( t + Δ t ) = {T}_{combined} ( t ) \cdot ℳ ( t ) \qquad ( 16 )$$

As illustrated in FIG. 4 or the like, the combined transition matrix T_{combined} includes elements, the number of which is equal to the square of the number of components of the magnetization vector, and includes many elements. If each element of the combined transition matrix T_{combined} is expressed by Ta, b, the combined transition matrix T_{combined} can be expressed by equation (17) below. Note that in equation (17), the number of components of the magnetization vector is put as “n”.

$${T}_{combined} ( t ) = ( \begin{matrix}{T}_{1 , 1} & … & {T}_{1 , n} \\ ⋮ & ⋱ & ⋮ \\ {T}_{n , 1} & … & {T}_{n , n}\end{matrix} ) \qquad ( 17 )$$

In the case of using the combined transition matrix, multiplication of the transition matrix including elements, the number of which is equal to the square of the number of components of the magnetization vector, is repeated K times in regard to each voxel. In a case where the examination target model is three-dimensional, the number of voxels exceeds one million in many cases, and the computation load, such as the computation amount or memory use amount due to computation, is very large.

A magnetic resonance numerical simulation apparatus according to the second embodiment aims at increasing the speed of the magnetic resonance numerical simulation, by applying the method of referring to only the contributory term according to the first embodiment to the combined transition matrix. Hereinafter, the magnetic resonance numerical simulation apparatus according to the second embodiment is described. In the description below, structural elements having substantially identical functions to the first embodiment are denoted by identical reference signs, and an overlapping description is given only where necessary.

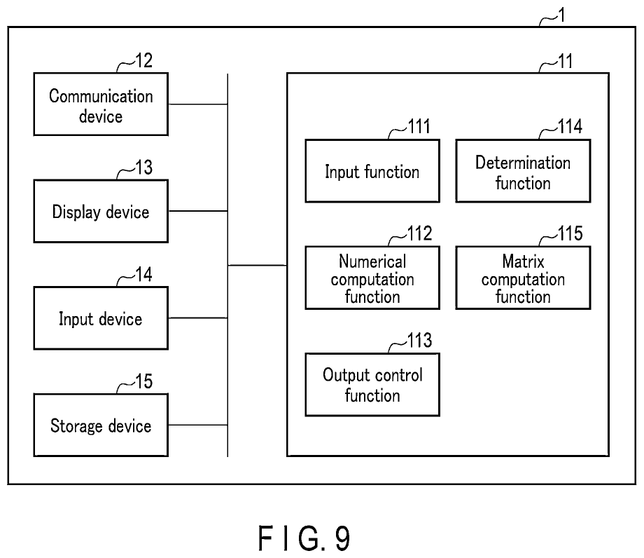

FIG. 9 is a diagram illustrating a configuration example of a magnetic resonance numerical simulation apparatus 1 according to the second embodiment. As illustrated in FIG. 9, processing circuitry 11 of the magnetic resonance numerical simulation apparatus 1 implements a determination function 114 and a matrix computation function 115, in addition to the input function 111, the numerical computation function 112 and the output control function 113. The functions 111 to 115 are not necessarily implemented by single processing circuitry. A plurality of independent processors may be combined to constitute processing circuitry, and the respective processors may implement the functions 111 to 115 by executing a physical simulation program. In addition, the functions 111 to 115 may be implemented as modules constituting the magnetic resonance numerical simulation program, or may be implemented as individual hardware.

By implementing the numerical computation function 112, the processing circuitry 11 applies the magnetization value and spatial partial differential value before update to the combined transition matrix, and computes the magnetization value and spatial partial differential value after update. It is assumed that the combined transition matrix is computed in advance by the matrix computation function 115, and is stored in the storage device 15. Since the update formula parameter of each matrix element of the combined transition matrix varies from sequence segment to sequence segment, the combined transition matrix is computed for each sequence segment and stored. In one example, the combined transition matrix may be stored by being correlated with an identifier representing a sequence segment.

By implementing the determination function 114, the processing circuitry 11 determines whether the combined transition matrix corresponding to the sequence segment of the target of arithmetic operation is stored in the storage device 15. If the processing circuitry 11 determines that the combined transition matrix is stored, the processing circuitry 11 reads out the combined transition matrix corresponding to the sequence segment of the target of arithmetic operation from the storage device 15, and uses the combined transition matrix.

By implementing the matrix computation function 115, the processing circuitry 11 computes each matrix element of the combined transition matrix, based on an output vector acquired by applying to the update formula an input vector including a predetermined magnetization value and a spatial partial differential value in each of a plurality of spatial directions. The combined transition matrix is stored in the storage device 15. In one example, in a case where the determination function 114 determines that the combined transition matrix corresponding to the sequence segment of the target of arithmetic operation is not stored in the storage device 15, the processing circuitry 11 may compute and use the combined transition matrix corresponding to the sequence segment. Note that in a case where the sequence is known in advance, the combined transition matrix may be computed in advance before the simulation. In addition, although the sequence segment that is the computation target of the combined transition matrix can be cut out, for example, based on the presence or absence of RF irradiation as a standard, the standard is not limited to this, and the sequence segment may be cut out based on any standard. Besides, there is no need to compute the combined transition matrix for all sequence segments, and the combined transition matrix may be computed for only some of the sequence segments.

Hereinafter, the magnetic resonance numerical simulation apparatus 1 according to the second embodiment is described in detail.

To begin with, matrix elements included in the combined transition matrix are described.

A first matrix element of the combined transition matrix, which contributes to the arithmetic operation of the time-dependent behavior of magnetic resonance, has a nonzero value, and a second matrix element of the combined transition matrix, which does not contribute to the arithmetic operation of the time-dependent behavior of magnetic resonance, has a zero value. Specifically, the first matrix element is a matrix element corresponding to a combination between a certain component of the magnetization vector and a component that interacts with this component, and the second matrix element is a matrix element corresponding to a combination between a certain component of the magnetization vector and a component that does not interact with this component.

To be more specific, Mₓ, M_{y} and M_{z} do not interact with components other than Mₓ, M_{y}, M_{z} and M₀. Accordingly, in regard to each of Mₓ, M_{y} and M_{z}, matrix elements of nonzero values are four matrix elements, namely Mₓ, M_{y}, M_{z} and M₀. ∂ₚM does not interact with ∂_{q}M (p≠q) and M₀. Accordingly, in regard to each of ∂ₚMₓ, ∂ₚM_{y} and ∂ₚM_{z}, matrix elements of nonzero values are six matrix elements, namely Mₓ, M_{y}, M_{z}, ∂ₚMₓ, ∂ₚM_{y} and ∂ₚM_{z}. In addition, since M₀ is a constant, all rows relating to M₀ can be excluded.

The processing circuitry 11 according to the second embodiment does not execute an arithmetic operation of the second matrix elements having zero values. Specifically, the second matrix elements having zero values are not incorporated into a computation formula of the combined transition matrix, and the computation formula is composed of the first matrix elements having nonzero values. Thereby, since the arithmetic operation of many second matrix elements having zero values can be omitted, the computation speed is increased.

Although the combined transition matrix is stored in the storage device 15, the storage device 15 stores first matrix elements having nonzero values, and does not store second matrix elements having zero values. Thereby, the memory capacity that stores the combined transition matrix can be reduced.

Next, the computation of the combined transition matrix by the matrix computation function 115 is described.

In a case where there is no diffusion term, each ∂ₚM is independent from ∂_{q}M (p≠q). The combined transition matrix can be computed based on an output vector corresponding to an input vector. The input vector includes a predetermined magnetization value and a spatial partial differential value in each of a plurality of spatial directions. The output vector is a magnetization vector acquired by applying a complex transition matrix to the input vector. Note that M₀ is invariable in each simulation.

All independent unit vectors are prepared as the input vector, and if the arithmetic operation described in the first embodiment is executed, the combined transition matrix can be easily obtained. Alternatively, since the combined transition matrix includes many elements of zero, a part of computation thereof can be omitted. For example, if the ω direction is not considered, the combined transition matrix can be obtained by computing only seven elements below. Note that if the ω direction is considered, it suffices that terms corresponding to ∂ω are added to V4 to V6.

$${M}_{x} = 1 , remainder 0. \qquad V1$$

$${M}_{y} = 1 , remainder 0. \qquad V2$$

$${M}_{z} = 1 , remainder 0. \qquad V3$$

$${\partial }_{x} {M}_{x} = {\partial }_{y} {M}_{x} = {\partial }_{z} {M}_{x} = 1 , remainder 0. \qquad V4$$

$${\partial }_{x} {M}_{y} = {\partial }_{y} {M}_{y} = {\partial }_{z} {M}_{y} = 1 , remainder 0. \qquad V5$$

$${\partial }_{x} {M}_{z} = {\partial }_{y} {M}_{z} = {\partial }_{z} {M}_{z} = 1 , remainder 0. \qquad V6$$

$$All 0. \qquad V7$$

For each of V1 to V7, the arithmetic operation described in the first embodiment is executed. The elements of the combined transition matrix corresponding to the update formula of M₀ are already known. If the elements of zero are utilized, the elements of the combined transition matrix corresponding to the update formula of Mₓ, M_{y}, M_{z} and M₀ can be acquired from V1, V2, V3 and V7. Similarly, if the elements of zero is utilized and the absence of mutual interference of each ∂ₚ is utilized, the elements of the combined transition matrix corresponding to ∂ₚ is acquired from the terms corresponding to ∂ₚ of V1, V2, V3, and V4 to V6.

In the case of using the Rodrigues' rotation formula, the combined transition matrix can be computed by sharing a part of intermediate computation in regard to computation of each of steps SA1, SA3 and SA4 illustrated in FIG. 8 of Example 2 of the first embodiment. Alternatively, the computation is possible by explicit writing of the matrix. In the case of software implementation with use of initial values, the time needed for computing the combined transition matrix can be shortened by batch-executing simulations for seven initial vectors in regard to each isochromat. In the case of computing the combined transition matrix by utilizing a matrix product of transition matrices, the time needed for computing the combined transition matrix can be shortened by dividing multiplications between respective partial matrices. In each of the cases, the time needed for computing the combined transition matrix can be shortened by sharing the values of sin, cos and exp as much as possible.

### Example 1

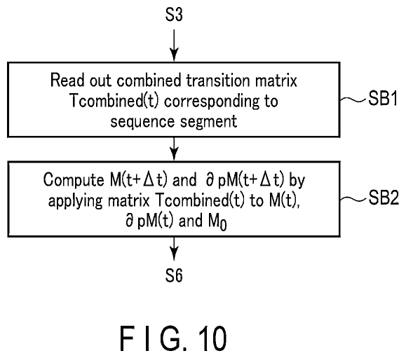

FIG. 10 is a diagram exemplarily illustrating a processing procedure of a magnetic resonance numerical simulation according to Example 1 of the second embodiment. FIG. 10 illustrates a process from step S3 to step S5 of FIG. 6. Each process of steps SB1 and SB2 is executed by the numerical computation function 112.

As illustrated in FIG. 10, if step S3 is executed, the processing circuitry 11 reads out a combined transition matrix T_{combined}(t) corresponding to the sequence segment input in step S1 from the storage device 15 (step SB1).

If step SB1 is executed, the processing circuitry 11 computes M(t+Δt) and ∂ₚM(t+Δt) after update, by applying M(t), ∂ₚM(t) and M₀ to the combined transition matrix T_{combined}(t) read out in step SB1 (step SB2). In step SB2, the processing circuitry 11 does not execute the arithmetic operation of the second matrix element of the zero value, and executes the arithmetic operation of the first matrix element of the nonzero value. Thereby, the computation time of the combined transition matrix can be shortened.

If step SB2 is executed, step S6 illustrated in FIG. 6 is executed.

### Example 2

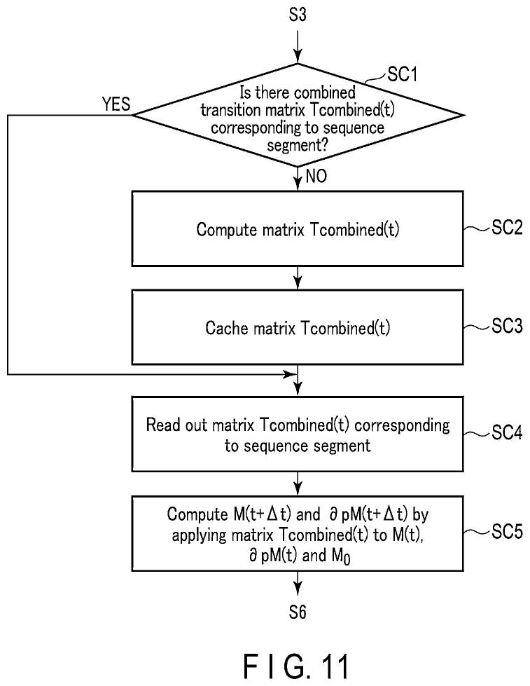

FIG. 11 is a diagram exemplarily illustrating a processing procedure of a magnetic resonance numerical simulation according to Example 2 of the second embodiment. FIG. 11 illustrates a process from step S3 to step S5 of FIG. 6.

As illustrated in FIG. 11, if step S3 is executed, the processing circuitry 11 determines, by implementing the determination function 114, whether a combined transition matrix T_{combined}(t) corresponding to the sequence segment input in step S1 is stored in the storage device 15 (step SC1).

If it is determined in step SC1 that the combined transition matrix T_{combined}(t) is not stored (step SC1: NO), the processing circuitry 11 computes, by implementing the matrix computation function 115, the combined transition matrix T_{combined}(t) corresponding to the sequence segment input in step S1 (step SC2).

If step SC2 is executed, the processing circuitry 11 caches, by implementing the output control function 113, the combined transition matrix T_{combined}(t) computed in step SC2 in the storage device 15 (step SC3). The combined transition matrix T_{combined}(t) is stored by being correlated with the identifier of the sequence segment input in step S1.

If step SC3 is executed or if it is determined in step SC1 that the combined transition matrix T_{combined}(t) is stored (step SC1: YES), the processing circuitry 11 reads out the combined transition matrix T_{combined}(t) corresponding to the sequence segment input in step S1 from the storage device 15 (step SC4).

If step SC4 is executed, the processing circuitry 11 computes, by implementing the numerical computation function 112, M(t+Δt) and ∂ₚM(t+Δt) after update, by applying M(t), ∂ₚM(t) and M₀ to the combined transition matrix T_{combined}(t) read out in step SC4 (step SC5).

If step SC5 is executed, step S6 illustrated in FIG. 6 is executed.

According to Example 2, the combined transition matrix T_{combined}(t) is computed each time an unknown sequence segment is detected, and the computation result is dynamically cached and reused, thereby achieving the increase in speed of the magnetic resonance numerical simulation.

### MODIFICATIONS

The process by the above-described magnetic resonance numerical simulation apparatus 1 is merely an example, and various additions, modifications and/or omissions can be made unless the gist of the present embodiment is changed.

### Modification 1

The processing circuitry 11 of the above-described embodiment is described as computing the numerical values after update of the computation target, by executing the arithmetic operation of the update formula relating to the computation target by using all numerical values before update belonging to the contributory terms among the numerical values before update of magnetization and the numerical values before update of the partial differentials. However, the present embodiment is not limited to this. The processing circuitry 11 does not need to use all numerical values before update belonging to the contributory terms, and may use on a part of all numerical values before update belonging to the contributory terms. In one example, processing circuitry 11 according to Modification 1 may not use a numerical value that is zero or can be regarded as zero, among the numerical values before update belonging to the contributory terms.

### Modification 2

In a case of computing a prediction output value of the A/D converter (ADC), processing circuitry 11 according to Modification 2 does not compute a partial differential value after update in a computation target direction for a magnetization component of the slice selection gradient magnetic field direction (z direction), but computes a partial differential value after update in a computation target direction for a magnetization component of a gradient magnetic field direction other than the slice selection gradient magnetic field direction. For example, in the case of computing the prediction output value of the A/D converter (ADC), the processing circuitry 11 according to Modification 2 may compute ∂ₚMₓ and ∂ₚM_{y} corresponding to the IQ signal, without computing ∂ₚM_{z}. The computation time for computing ∂ₚM_{z} can be reduced, and the computation time of the prediction output value of the A/D converter (ADC) can be shortened.

Note that the processing circuitry 11 may execute ADC computation of a continuous system using a spatial partial differential. This can be executed by similar computation to Non Patent Literature 3 using a diffusion term.

According to at least one of the above-described embodiments, the computation efficiency of a magnetic resonance numerical simulation can be improved.

The term “processor” used in the above description means, for example, circuitry such as a CPU, a GPU, an application specific integrated circuit (ASIC), a programmable logic device (for example, a simple programmable logic device (SPLD), or a complex programmable logic device (CPLD)), and a field programmable gate array (FPGA). The processor implements functions by reading and executing a program stored in the storage circuitry. Note that, instead of storing the program in the storage circuitry, such a configuration may be adopted that the program is directly assembled in the circuitry of the processor. In this case, the processor implements functions by reading and executing the program assembled in the circuitry of the processor. On the other hand, in a case where the processor is, for example, an ASIC, the functions are directly assembled as logic circuitry in the circuitry of the processor, instead of the program being stored in the storage circuitry. Note that the processors in the embodiments are not limited to cases where each processor is constituted as single circuitry, and a plurality of independent circuities may be combined to constitute one processor and to implement functions thereof. Furthermore, a plurality of constituent elements in FIG. 1 and FIG. 9 may be integrated into one processor, and the processor may implement the functions thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance numerical simulation apparatus comprising processing circuitry configured to:
input, in regard to an isochromat, a numerical value before update of magnetization, and a numerical value before update of a partial differential for the magnetization in each of a spatial direction and/or an angular frequency direction; and
execute an arithmetic operation of an update formula representing a time-dependent behavior of magnetic resonance, by using a part of the numerical values before update of the magnetization, and the numerical values before update of the partial differential, and compute, in regard to the isochromat, a numerical value after update of the magnetization, and a numerical value after update of the partial differential for the magnetization in a computation target direction of the spatial direction and/or the angular frequency direction.

2. The magnetic resonance numerical simulation apparatus of claim 1, wherein the processing circuitry is configured to:
execute the arithmetic operation of the update formula by using the numerical value before update of the magnetization, without using the numerical value before update of the partial differential, and compute the numerical value after update of the magnetization, and
execute the arithmetic operation of the update formula by using the numerical value before update of the partial differential in the computation target direction, without using the numerical value before update of the partial differential in a non-computation target direction of the spatial direction and/or the angular frequency direction, and compute the numerical value after update of the partial differential in the computation target direction.

3. The magnetic resonance numerical simulation apparatus of claim 2, wherein
the update formulae include a magnetization update formula, a spatial partial differential update formula, and an angular frequency partial differential update formula, which are separated from each other, and
the processing circuitry is configured to:
execute an arithmetic operation of the magnetization update formula by referring to the numerical value before update of the magnetization, thereby to compute the numerical value after update of the magnetization;
execute an arithmetic operation of the spatial partial differential update formula by referring to the numerical value before update of the magnetization and the numerical value before update of the partial differential in the spatial direction of the computation target direction, thereby to compute the numerical value after update of the partial differential in the spatial direction of the computation target direction; and
execute an arithmetic operation of the angular frequency partial differential update formula by referring to the numerical value before update of the magnetization and the numerical value before update of the partial differential in the angular frequency direction, thereby to compute the numerical value after update of the partial differential in the angular frequency direction.

4. The magnetic resonance numerical simulation apparatus of claim 3, wherein the processing circuitry is configured to:
compute a magnetization rotation term value by executing an arithmetic operation of a rotation term in the magnetization update formula by referring to the numerical value before update of the magnetization; and
compute the numerical value after update of the magnetization by applying a relaxation term in the magnetization update formula to the magnetization rotation term value.

5. The magnetic resonance numerical simulation apparatus of claim 4, wherein the processing circuitry is configured to:
compute a partial differential rotation term value by executing an arithmetic operation of a rotation term in the spatial partial differential update formula and/or the angular frequency partial differential update formula by referring to the numerical value before update of the magnetization and the numerical value before update of the partial differential in the computation target direction; and
compute the numerical value after update of the partial differential in the computation target direction by applying a relaxation term in the spatial partial differential update formula and/or the angular frequency partial differential update formula to the partial differential rotation term value.

6. The magnetic resonance numerical simulation apparatus of claim 5, wherein the spatial partial differential update formula includes a first term that depends on an effective magnetic field vector component in an orthogonal direction to a slice selection gradient magnetic field direction, a second term that depends on an effective magnetic field vector component in the slice selection gradient magnetic field direction, and a third term that does not depend on the effective magnetic field vector components, the first term, the second term and the third term being separated from each other.

7. The magnetic resonance numerical simulation apparatus of claim 6, wherein the processing circuitry is configured to:
execute an arithmetic operation of the first term, the second term and the third term in an application period of an RF pulse; and
execute an arithmetic operation of the second term and third term in a nonapplication period of the RF pulse.

8. The magnetic resonance numerical simulation apparatus of claim 6, wherein the processing circuitry is configured to execute an arithmetic operation of the first term, the second term and the third term in an application period and a nonapplication period of an RF pulse.

9. The magnetic resonance numerical simulation apparatus of claim 6, wherein the processing circuitry is configured to:
compute a first rotation term value by executing an arithmetic operation of a rotation term of the first term by referring to the numerical value before update of the magnetization and the numerical value before update of the spatial partial differential in the computation target direction, compute a second rotation term value by executing an arithmetic operation of a rotation term of the second term by referring to the numerical value before update of the magnetization and the numerical value before update of the spatial partial differential in the computation target direction, and compute a third rotation term value by executing an arithmetic operation of a rotation term of the third term by referring to the numerical value before update of the magnetization and the numerical value before update of the spatial partial differential in the computation target direction, thereby to compute the numerical value after update of the spatial partial differential in the computation target direction; and
compute the numerical value after update of the spatial partial differential in the computation target direction by applying a relaxation term in the spatial partial differential update formula to an addition value of the first rotation term value, the second rotation term value and the third rotation term value.

10. The magnetic resonance numerical simulation apparatus of claim 2, wherein the update formula is a combined transition matrix in which a plurality of transition matrices each describing a time-dependent behavior of the magnetization and a time-dependent behavior of the partial differential in each of a plurality of time steps are combined.

11. The magnetic resonance numerical simulation apparatus of claim 10, wherein
a first matrix element contributing to an arithmetic operation of a time-dependent behavior of magnetic resonance in the combined transition matrix has a nonzero value,
a second matrix element not contributing to the arithmetic operation of the time-dependent behavior of the magnetic resonance in the combined transition matrix has a zero value, and
the processing circuitry is configured to not execute an arithmetic operation of the second matrix element having the zero value.

12. The magnetic resonance numerical simulation apparatus of claim 11, further comprising a memory configured to store the combined transition matrix,
wherein the memory is configured to store the first matrix element and to not store the second matrix element.

13. The magnetic resonance numerical simulation apparatus of claim 10, wherein the processing circuitry is configured to compute each of matrix elements of the combined transition matrix, based on an output vector acquired by applying to the update formula an input vector including a predetermined numerical value of magnetization and a numerical value of a spatial partial differential of magnetization in each of the spatial directions.

14. The magnetic resonance numerical simulation apparatus of claim 10, further comprising a memory configured to store a combined transition matrix in regard to each of sequence segments of a pulse sequence,
wherein the processing circuitry is configured to:
determine whether a combined transition matrix corresponding to a sequence segment of an arithmetic operation target is stored in the memory;
read out and use the combined transition matrix corresponding to the sequence segment of the arithmetic operation target, in a case where the combined transition matrix is determined to be stored; and
compute a combined transition matrix corresponding to the sequence segment of the arithmetic operation target, in a case where the combined transition matrix is determined to be not stored, and use the computed combined transition matrix.

15. The magnetic resonance numerical simulation apparatus of claim 1, wherein, in a case of computing a prediction output value of an A/D converter, the processing circuitry is configured to not compute the numerical value after update of the partial differential in the computation target direction for a magnetization component of a slice selection gradient magnetic field direction, but configured to compute the numerical value after update of the partial differential in the computation target direction for a magnetization component of a gradient magnetic field direction other than the slice selection gradient magnetic field direction.

16. A magnetic resonance numerical simulation method comprising:
inputting, in regard to an isochromat, a numerical value before update of magnetization, and a numerical value before update of a partial differential for the magnetization in each of a spatial direction and/or an angular frequency direction; and
executing an arithmetic operation of an update formula representing a time-dependent behavior of magnetic resonance by using a part of the numerical values before update of the magnetization and the numerical values before update of the partial differential, and computing, in regard to the isochromat, a numerical value after update of the magnetization, and a numerical value after update of the partial differential for the magnetization in a computation target direction of the spatial direction and/or the angular frequency direction.
